(19) United States
(12) Patent Application Publication
(10) Pub. No.: US 2002/0063334 A1
(43) Pub. Date: May 30, 2002

(54) Integrated circuit devices having a composite insulation layer and methods of manufacturing same

(76) Inventors: Hong-Jae Shin, Seoul (KR); Won-Jin Kim, Kyunggi-do (KR)

Correspondence Address: MYERS BIGEL SIBLEY & SAJOVEC, PO BOX 37428, RALEIGH, NC, 27627, US

(21) Appl. No.: 09/991,829

(22) Filed: Nov. 5, 2001

(30) Foreign Application Priority Data
Nov. 30, 2000 (KR) 2000-72093

(51) Int. Cl. H01L 21/31; H01L 23/48

(52) U.S. Cl. 257/758

(57) ABSTRACT

An integrated circuit device includes a substrate that has a pattern formed thereon. The pattern may have two or more mesa regions. A spin on glass insulation layer is disposed between the pair of mesa regions and a second insulation layer is disposed on the spin on glass insulation layer, at least partially in the gap between the mesas, to form a composite insulation layer. The second insulation layer may be SiO₂, SiN, and/or SiON. The spin on glass may be polysilazane, hydro silsesquioxane, silicate, and/or methyl silsesquioxane.

### RELATED APPLICATION

This application claims the benefit of Korean Patent Application No. 2000-072093, filed Nov. 30, 2000, the disclosure of which is hereby incorporated herein by reference.

### FIELD OF THE INVENTION

The present invention relates generally to integrated circuit devices and manufacturing methods therefor and, more particularly, to insulation layers that may be used to fill space between integrated circuit patterns and manufacturing methods therefor.

### BACKGROUND OF THE INVENTION

In general, integrated circuit devices have become more highly integrated and may have multilevel architectures and/or minute elements therein. In highly integrated devices, an aspect ratio of a contact hole or a via hole that connects an upper and a lower element may be relatively high. Moreover, step coverage of an insulation layer may vary between high density patterns and low density patterns and/or between upper patterns and lower patterns. An insulation layer that provides good step coverage for a lower pattern, however, may cause problems in patterning an upper interconnection or element. Thus, it may be desirable to reduce the step coverage of an insulation layer depending on the region of an integrated circuit device. For example, it is common in dynamic random access memory (DRAM) manufacturing to fill narrow grooves between gate lines and/or bit lines formed at a substrate with an interlayer insulation layer, and then to planarize a top side of the interlayer insulation layer.

One approach to reducing the step coverage of an insulation layer is to form a layer of boro-phospho-silicate-glass (BPSG) and then reflow the BPSG layer at a temperature over 830° C. Unfortunately, in highly integrated circuit devices, transistors may have a critical dimension of 0.2 microns or less. The thermal treatments of the BPSG layer, may adversely affect such transistors.

Other materials and methods may be used in forming insulation layers, such as tetra-ethyl-ortho-silicate (ozone-TEOS), undoped silicate glass (USG), and high-density plasma chemical vapor deposition (HDP-CVD). Such materials and methods, however, may result in a void or a seam when used in integrated circuit devices that follow a design rule of 0.2 microns or less.

FIG. 1 is a scanning electron microscope picture that illustrates defects in a conventional HDP-CVD oxide insulation layer that is formed on a highly integrated circuit device. The insulation layer fills a gap between bit lines in which the width of the gap is approximately 4700 Å and the height of the gap is about 10,300 Å. Unfortunately, the void shown in dark black in FIG. 1 may result in cracks in subsequent processes. Thus, the reliability of an integrated circuit device may be degraded.

Another material that may be used in insulation layers is spin on glass (SOG). In general, SOG has relatively good gap filling properties, and may compensate for step coverage when thickly formed. After an integrated circuit device is coated with an SOG layer, densification and curing steps may be performed to eliminate unstable components from the SOG layer. For example, an SOG layer may be heated to a temperature between approximately 100° C. and 300° C. to remove a solvent component. The SOG layer may be further heated to a temperature of about 400° C. and/or may be annealed at a temperature of over 600° C. Unfortunately, SOG layers may be susceptible to cracks in thickly formed regions. Furthermore, chemical mechanical polishing is frequently performed to reduce the step coverage in SOG layers.

Even if an SOG layer is thermally treated, residual components may remain in the SOG layer that may degrade the characteristics of the SOG layer. For example, residual components such as organics, hydrics, and or other inorganic materials may cause problems relating to pollution of the device, the absorption of water, and the porousness of an SOG layer. In particular, residual components may remain in lower portions of gaps having high aspect ratios as the thermal treatment is generally more effective near the surface of an SOG layer.

If an SOG layer is left in a porous state due to the presence of residual components, then the porous regions of the SOG layer may etch more rapidly than other portions of the SOG layer. Moreover, stress differences due to thermal expansion may increase defect generation and may also reduce element reliability in an integrated circuit device.

For example, if a field effect transistor, such as a metal oxide semiconductor (MOS) transistor, is formed on a substrate with an inorganic SOG layer, such as hydro silsesquioxane (HSQ) or polysilazane, a porous layer may be formed in deep portions between the gate line. The porous lower portion of the SOG layer may be exposed when forming a pad for a storage node contact or a bit line contact. Unfortunately, even small doses of etchant used in a cleaning step may erode the exposed lower SOG layer. As a result, a pipeline type bridge may be formed between adjacent pads through the exposed lower SOG layers, which may cause a short between electrical wires.

### SUMMARY OF THE INVENTION

According to embodiments of the present invention, an integrated circuit device comprises a substrate that has a pattern formed thereon. The pattern may comprise two or more mesa regions. A spin on glass insulation layer is disposed between the pair of mesa regions and a second insulation layer is disposed on the spin on glass insulation layer, at least partially in the gap between the mesas, to form a composite insulation layer. The second insulation layer may comprise SiO₂, SiN, and/or SiON. The spin on glass may comprise polysilazane, hydro silsesquioxane, silicate, and/or methyl silsesquioxane. Advantageously, the composite insulation layer may resist the formation of voids when applied in gaps having a high aspect ratio.

In other embodiments, the spin on glass insulation layer has a thickness as measured from the substrate to a top surface thereof that is approximately 20%-80% of a thickness of one or more of the mesa regions as measured from the substrate to a top surface thereof.

In still other embodiments, an adhesive layer may be disposed between the spin on glass layer and the substrate, and each mesa region may comprise an etch resistant layer at an upper surface thereof opposite the substrate. The etch resistant layer may comprise SiC, SiN, and/or SiO₂.

### BRIEF DESCRIPTION OF THE DRAWINGS

FIG. 1 is a scanning electron microscope picture that illustrates defects in a conventional HDP-CVD oxide insulation layer that is formed on a highly integrated circuit device;

FIGS. 2-5 are cross sectional views that illustrate integrated circuit devices having composite insulation layers and methods of manufacturing same in accordance with embodiments of the present invention; and

FIG. 6 is a scanning electron microscope picture that illustrates an integrated circuit device having a composite insulation layer in accordance with embodiments of the present invention.

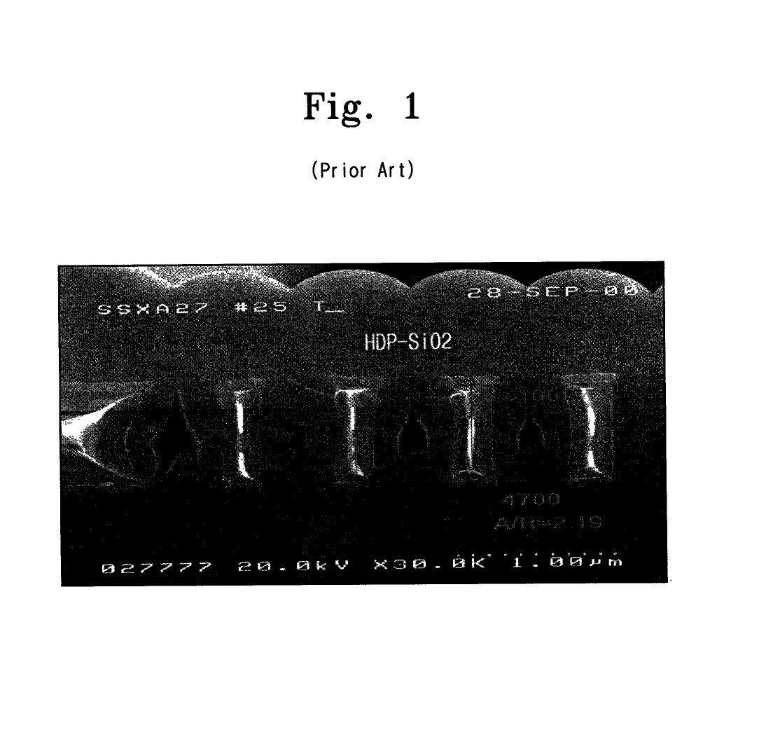

### DETAILED DESCRIPTION OF PREFERRED EMBODIMENTS

While the invention is susceptible to various modifications and alternative forms, specific embodiments thereof are shown by way of example in the drawings and will herein be described in detail. It should be understood, however, that there is no intent to limit the invention to particular forms disclosed, that on the contrary, the invention is to cover all modifications, equivalents, and alternatives falling within the spirit and scope of the invention as defined by the claims. In the drawings, the thickness of layers and regions are exaggerated for clarity. Like numbers refer to like elements throughout the description of the figures. It will also be understood that when an element, such as a layer, region, or substrate is referred to as being on another element, it can be directly on another element or intervening elements may be present. In contrast, when an element, such as a layer, region, or substrate is referred to as being directly on another element, there are no intervening elements present.

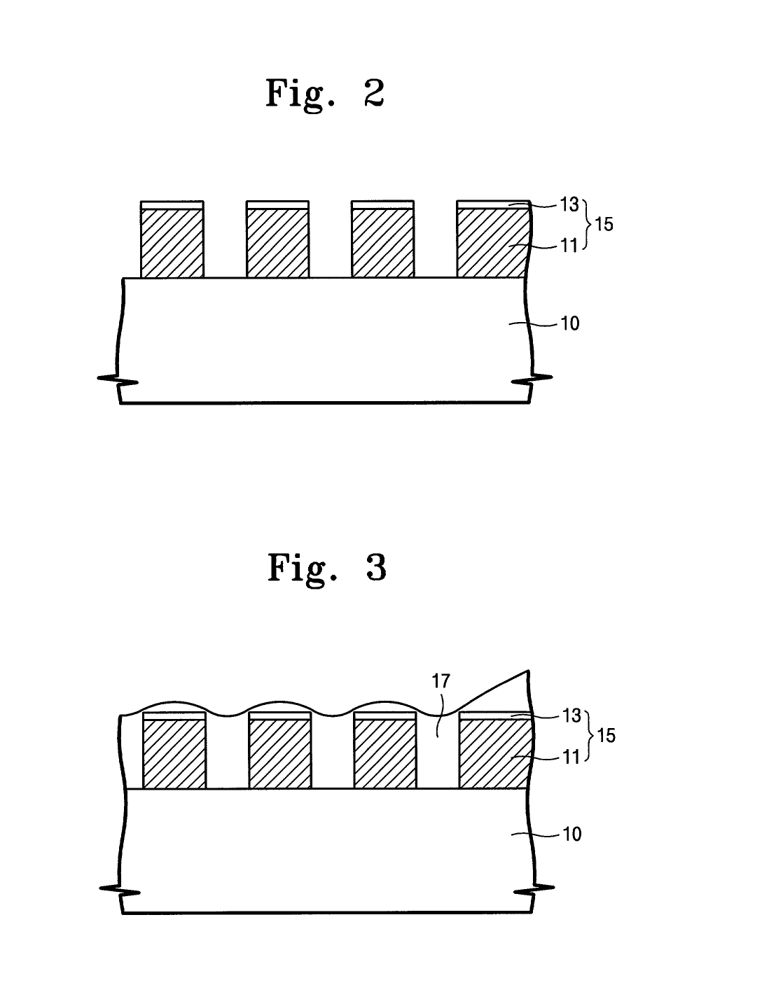

FIGS. 2-5 are cross sectional views that illustrate integrated circuit devices having composite insulation layers and methods of manufacturing same in accordance with embodiments of the present invention.

Referring now to FIG. 2, a pattern 15, which may be a bit line pattern, is formed on a substrate 10. A MOS transistor structure (not shown in FIG. 2) may be formed in the substrate 10 under the pattern 15. The pattern 15 may be formed by depositing a conductive layer 11 on the substrate 10 and then, optionally, depositing a protective layer 13 on the conductive layer 11. The pattern 15 shown in FIG. 2 may then be formed using photolithography and etching procedures. In accordance with embodiments of the present invention, the conductive layer 11 may comprise polysilicone, metal, and/or metal silicide. The protective layer 13 may comprise SiC, SiN, and/or SiO₂, which may protect against a dry anisotropic etch.

Referring now to FIG. 3, a SOG layer 17 is spin coated over the substrate 10 and the pattern 15 and substantially fills gaps between bit line mesas comprising the pattern 15. As shown in FIG. 3, the SOG layer 17 covers the protective layer 13. The thickness and form of the resulting SOG layer 17 may be modified by adjusting a proportion of a solid component in an SOG coating solution in the sol state. In accordance with embodiments of the present invention, the SOG layer 17 may comprise an inorganic material, such as HSQ and/or an organic material, such as methyl silsesquioxane (MSQ). After coating the substrate 10 and the pattern 15 with the SOG layer 17, the resulting structure may be thermally treated to remove a solvent component from the SOG layer 17, and an annealing process may be performed to densify and cure the SOG layer 17.

In other embodiments of the present invention, an adhesive layer such as an HDP-CVD oxide layer, may be applied to the substrate 10 and the pattern 15 before forming the SOG layer 17. The adhesive layer may have a thickness between several tens and several hundreds of angstroms.

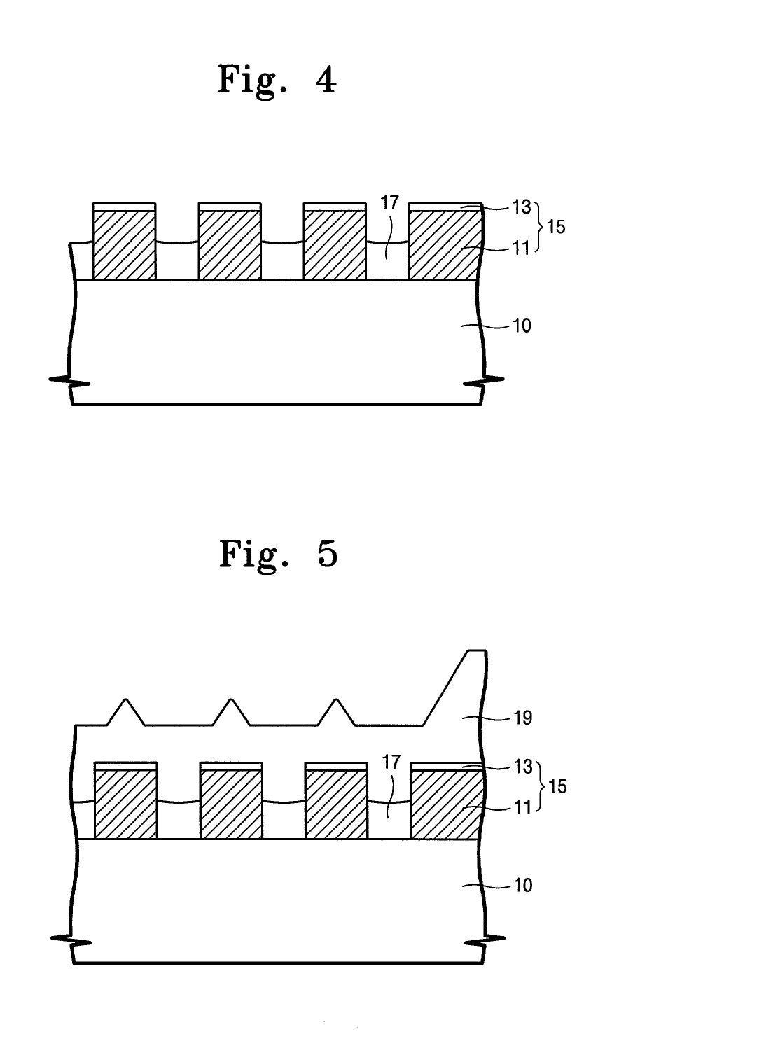

Referring now to FIG. 4, an isotropic dry etch process is performed using, for example, a CF or a CHF series etch gas to recess the SOG layer 17 below an upper surface of the mesas comprising the pattern 15. The degree to which the SOG layer 17 is recessed may be adjusted based on the aspect ratio of the gap between the mesas comprising the pattern 15. For example, in regions having a low aspect ratio in which the gap between the mesas comprising the pattern 15 is wide, the SOG layer 17 may be substantially removed. By contrast, in other regions having high aspect ratios, the SOG layer 17 may remain relatively thick. For integrated circuit devices having relatively dense bit line patterns, it may be desirable to etch the SOG layer until approximately 20% to 80% of a pattern 15 mesa sidewall is exposed. The protective layer 13 may protect the pattern 15 from being damaged from the anisotropic dry etch. If the SOG layer 17 is not sufficiently cured from the previous thermal treatment, then an additional thermal treatment may be performed after completing the etch process.

Referring now to FIG. 5, an HDP-CVD insulation layer 19 is formed within the trench on the SOG layer 17 and extends onto the pattern 15. The HDP-CVD layer 19 may comprise an oxide layer (e.g., HDP-CVD SiO₂), a SiN layer, and/or a SiON layer, in accordance with embodiments of the present invention. Thus, a composite insulation layer comprising the SOG layer 17 and the HDP-CVD layer 19 may be formed without generating a void or a seam therein. The resultant structure may be further processed by forming a plasma enhanced chemical vapor deposition (PECVD) oxide layer thereon, or by planarizing the surface using, for example, a CMP process.

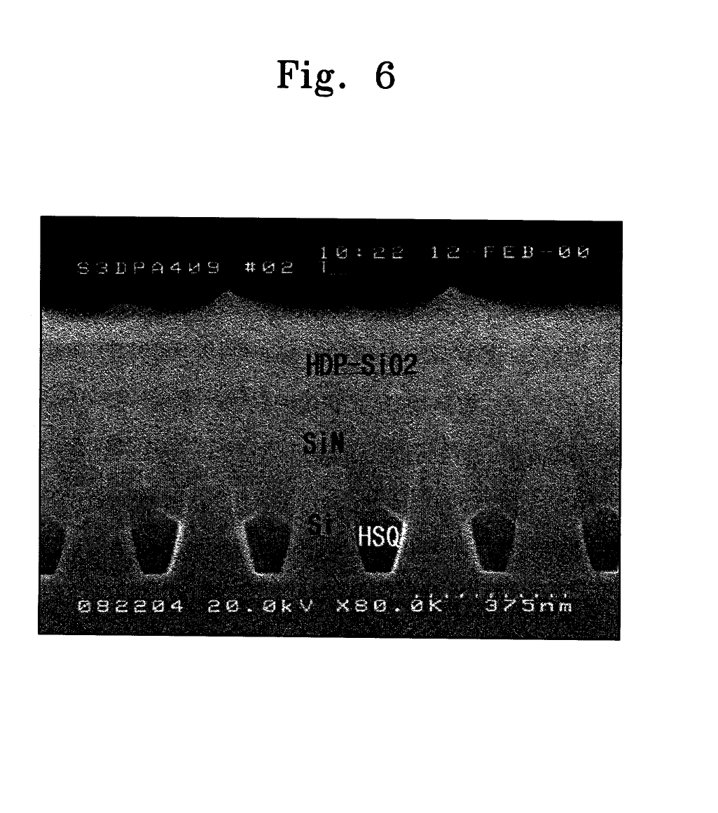

Referring now to FIG. 6, a SEM picture illustrates an integrated circuit device having a composite insulation layer in accordance with embodiments of the present invention. As shown in FIG. 6, a SiN layer is formed on a Si substrate, and then a trench having an aspect ratio of about 2.5 is formed using a dry etch technique. An HSQ layer is formed on the substrate and then etched to leave about 50% of the HSQ layer in the trenches. An HDP-CVD oxide layer is then formed on the HSQ layer to create a composite insulation layer. Advantageously, the composite insulation layer does not contain any voids.

In concluding the detailed description, it should be noted that many variations and modifications can be made to the preferred embodiments without substantially departing from the principles of the present invention. All such variations and modifications are intended to be included herein within the scope of the present invention, as set forth in the following claims.

We claim:

1. An integrated circuit device, comprising:
a substrate having a pattern formed thereon that comprises a pair of mesa regions;
a spin on glass insulation layer disposed between the pair of mesa regions; and
an insulation layer disposed on the spin on glass insulation layer between the pair of mesa regions.

2. The integrated circuit device of claim 1, wherein the spin on glass insulation layer has a thickness as measured from the substrate to a top surface thereof, opposite the substrate, that is approximately 20%-80% of a thickness of at least one of the mesa regions as measured from the substrate to a top surface thereof, opposite the substrate.

3. The integrated circuit device of claim 1, wherein the spin on glass is selected from the group consisting of polysilazane, hydro silsesquioxane, silicate, and methyl silsesquioxane.

4. The integrated circuit device of claim 1, wherein the insulation layer is selected from the group consisting of a SiO₂ layer, a SiN layer, and a SiON layer.

5. The integrated circuit device of claim 1, further comprising an adhesive layer between the spin on glass layer and the substrate.

6. A method of manufacturing an integrated circuit device, comprising:
forming a pattern comprising a pair of mesa regions on a substrate;
forming a spin on glass insulation layer between the pair of mesa regions; and
forming an insulation layer selected from the group consisting of a SiO₂ layer, a SiN layer, and a SiON layer on the spin on glass insulation layer between the pair of mesa regions.

7. A method of manufacturing an integrated circuit device, comprising:
forming a pattern comprising a pair of mesa regions on a substrate;
coating the pattern and the substrate with a spin on glass layer;
etching the spin on glass layer such that the spin on glass layer is recessed from upper surfaces of the mesa regions opposite the substrate; and
depositing an insulation layer on the etched spin on glass layer between the pair of mesa regions.

8. The method of claim 7, wherein etching the spin on glass layer comprises:
etching the spin on glass layer until approximately 20%-80% of a sidewall of at least one of the mesa regions is exposed.

9. The method of claim 7, further comprising:
thermally treating the integrated circuit device before etching the spin on glass layer.

10. The method of claim 7, further comprising:
thermally treating the integrated circuit device after etching the spin on glass layer.

11. A method for forming an insulating layer in a semiconductor memory device, comprising the steps of:
forming a SOG (spin on glass) insulating layer on a substrate forming stepped patterns;
leaving the SOG insulating layer recessed lower than a top surface of the pattern in at least a part of stepped spaces between the patterns by etching the SOG insulating layer; and
depositing a CVD (chemical vapor deposition) insulating layer over the recessed SOG insulating layer.

12. The method of claim 11, wherein the step of recessing the SOG layer by etching is performed by an anisotropic etch (etch back) on the entire surface thereof.

13. The method of claim 11, wherein the SOG layer is made of inorganic SOG group of HSQ (hydro silsesquioxane) series, and the etching steps thereof is performed by a dry anisotropic etch.

14. The method of claim 11, the method further comprising a step of forming an insulating adhesive layer capable of improving an adhesive force with a lower layer before forming the SOG layer.

15. The method of claim 14, wherein the adhesive layer is formed by HDP-CVD (high density plasma chemical vapor deposition), and made of SiO₂, SiN, or SiON.

16. The method of claim 11, wherein the residual SOG insulating layer is formed by recessing the SOG layer with an etch, and then curing the recessed SOG layer.

17. A semiconductor device comprising:
a substrate forming stepped patterns;
a SOG insulating layer filling a part of the step coverage in a lower space between the patterns; and
a CVD insulating layer stacked on the SOG insulating layer and the pattern over the substrate.

18. The device of claim 17, wherein the SOG layer fills 20 to 80% of a depth of the space between the patterns.

19. The device of claim 17, wherein an aspect ratio in gap of the stepped pattern is more than 2.

20. The device of claim 17, wherein the SOG insulating layer is made of organic SOG layer.

21. The device of claim 17, wherein a top surface of the pattern has an etch protecting layer made of SiC, or SiN.
